(19) United States
(12) Patent Application Publication
(10) Pub. No.: US 2020/0336120 A1
(43) Pub. Date: Oct. 22, 2020

(54) HARMONIC PROCESSING CIRCUIT AND AMPLIFICATION CIRCUIT

(71) Applicant: SUMITOMO ELECTRIC INDUSTRIES, LTD., Osaka-shi, Osaka (JP)

(72) Inventor: Noriyoshi SUDA, Osaka-shi, Osaka (JP)

(73) Assignee: SUMITOMO ELECTRIC INDUSTRIES, LTD., Osaka-shi, Osaka (JP)

(21) Appl. No.: 16/957,586

(22) PCT Filed: Mar. 26, 2018
(86) PCT No.: PCT/JP2018/012041

§ 371 Date: Jun. 24, 2020

(30) Foreign Application Priority Data
Dec. 28, 2017 (JP) 2017-254355

(51) Int. Cl. H03F 1/56; H03F 3/04

(52) U.S. Cl. CPC H03F 1/565; H03F 2200/222; H03F 3/04

(57) ABSTRACT

A harmonic processing circuit includes: a first feeder line branching from a signal line configured to transmit a signal to be inputted to or outputted from an amplifier; and a first setting unit connected to the first feeder line and configured to set an impedance in the signal line to a harmonic of the signal. At least part of the first setting unit is configured by a lumped circuit.

### TECHNICAL FIELD

The present invention relates to a harmonic processing circuit and an amplification circuit.

This application claims priority on Japanese Patent Application No. 2017-254355 filed on Dec. 28, 2017, the entire contents of which are incorporated herein by reference.

### BACKGROUND ART

Conventionally, in order to perform harmonic processing for improving power efficiency of an amplifier, an open stub, which adjusts an impedance to a harmonic to an appropriate value, is generally provided to a signal line (see Patent Literature 1, for example).

### CITATION LIST

### Patent Literature

PATENT LITERATURE 1: Japanese Laid-Open Patent Publication No. 2011-66839

### SUMMARY OF INVENTION

A harmonic processing circuit according to one embodiment includes: a branch line branching from a signal line configured to transmit a signal to be inputted to or outputted from an amplifier; and a setting unit connected to the branch line and configured to set an impedance in the signal line to a harmonic of the signal. At least part of the setting unit is configured by a lumped circuit.

### BRIEF DESCRIPTION OF DRAWINGS

FIG. 1 is a block diagram showing a configuration of a Doherty amplification circuit according to an embodiment.

FIG. 2 is a plan view of the Doherty amplification circuit.

FIG. 3 is a block diagram showing a configuration of a first harmonic processing circuit.

FIG. 4 is a Smith chart showing load impedances in response to frequency change in a signal in an amplification circuit according to an example.

FIG. 5 is a block diagram showing a configuration of a harmonic processing circuit provided on a gate terminal side.

### DESCRIPTION OF EMBODIMENTS

### Problems to be Solved by the Disclosure

The size of the above-described open stub as a circuit for performing harmonic processing is determined based on the wavelength of a signal to be processed. That is, a certain size needs to be secured for the open stub, and therefore, miniaturization thereof is difficult.

The present disclosure has been made in view of the above situation, and an object of the present disclosure is to provide a harmonic processing circuit and an amplification circuit which can be miniaturized.

### Advantageous Effects of the Present Disclosure

According to the present disclosure, miniaturization of a harmonic processing circuit is realized.

First, contents of embodiments are listed and described.

### Outline of Embodiments

(1) A harmonic processing circuit according to one embodiment includes: a branch line branching from a signal line configured to transmit a signal to be inputted to or outputted from an amplifier; and a setting unit connected to the branch line and configured to set an impedance in the signal line to a harmonic of the signal. At least part of the setting unit is configured by a lumped circuit

According to the harmonic processing circuit of the above configuration, since at least part of the setting unit for setting an impedance to a harmonic is configured by the lumped circuit, the size of the setting unit can be reduced as compared to the case where harmonic processing is performed using an open stub. Thus, miniaturization of the entire circuit can be achieved.

(2) In the above harmonic processing circuit, the branch line is preferably a feeder line for the amplifier.

In this case, by using an existing feeder line as the branch line, the setting unit can be provided without adding a new line.

Thus, even if the harmonic processing circuit is provided to a circuit having an amplifier, the circuit is inhibited from being increased in size due to the provision of the harmonic processing circuit.

(3) In the above harmonic processing circuit, the setting unit is preferably set such that the branch line is open with respect to a fundamental frequency of the signal.

In this case, the setting unit is inhibited from adversely affecting the fundamental frequency.

(4) In the above harmonic processing circuit, the amplifier is preferably housed in a single package together with another amplifier.

In this case, since the signal line connected to the amplifier and a signal line of the other amplifier are arranged adjacent to each other, a space around the signal lines is limited. Even in this case, since the harmonic processing circuit can achieve miniaturization of the entirety thereof, appropriate arrangement can be achieved even when the space around the signal lines is limited.

(5) In the above harmonic processing circuit, the setting unit includes a plurality of capacitive elements connected in parallel. A capacitance of a capacitive element connected in a position adjacent to a voltage source for applying a voltage to the feeder line among the plurality of capacitive elements is a capacitance that causes a short circuit with respect to the fundamental frequency of the signal.

In this case, a high-frequency signal is prevented from leaking to the voltage source side of the feeder line.

(6) In the above harmonic processing circuit, preferably, the setting unit includes: a first inductive element connected to the branch line; a second inductive element connected between the first inductive element and the voltage source for applying a voltage to the feeder line; a first capacitive element having an end connected to a connection point between the first inductive element and the second inductive element; and a second capacitive element having an end connected to a connection point between the second inductive element and the voltage source. Preferably, an inductance of the second inductive element is a value greater than an inductance of the first inductive element, and a capacitance of the second capacitive element is a value greater than a capacitance of the first capacitive element.

In this case, the values of the respective elements can be appropriately set.

(7) An amplification circuit according to another embodiment includes: an amplifier; a signal line configured to transmit a signal to be inputted to or outputted from the amplifier; and the harmonic processing circuit according to any one of above (1) to (6).

### Details of Embodiments

Hereinafter, preferred embodiments will be described with reference to the drawings.

It should be noted that at least some parts of the embodiments described below may be combined together as desired.

### [Configuration of Doherty Amplification Circuit]

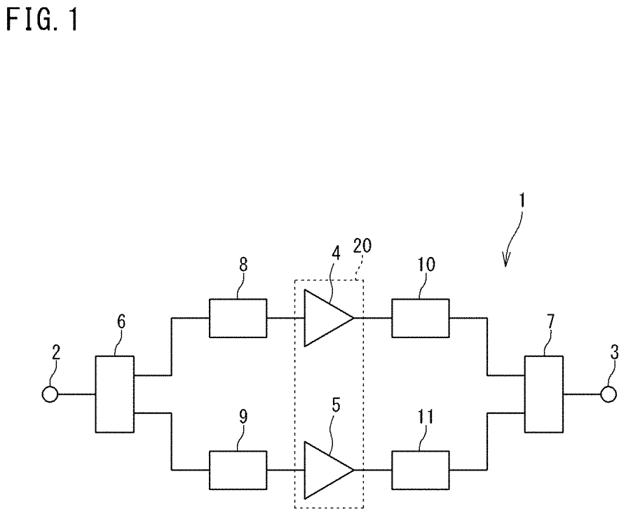

FIG. 1 is a block diagram showing the configuration of a Doherty amplification circuit according to an embodiment.

The Doherty amplification circuit 1 is mounted on a wireless communication apparatus such as a base station apparatus in a mobile communication system, and amplifies a transmission signal having a radio frequency (RF signal).

The Doherty amplification circuit 1 amplifies an RF signal (input signal) provided to an input terminal 2, and outputs a resultant signal from an output terminal 3.

As shown in FIG. 1, the Doherty amplification circuit 1 includes: a carrier amplifier 4; a peak amplifier 5 connected in parallel to the carrier amplifier 4; a divider 6; a combiner 7 that combines outputs from the carrier amplifier 4 and the peak amplifier 5; a carrier-side input matching circuit 8; a peak-side input matching circuit 9; a carrier-side output matching circuit 10; and a peak-side output matching circuit 11.

The divider 6 is connected to a stage subsequent to the input terminal 2, and distributes the RF signal provided from the input terminal 2 to the carrier amplifier 4 and the peak amplifier 5.

An output from the divider 6 is provided to the carrier amplifier 4 via the carrier-side input matching circuit 8, and to the peak amplifier 5 via the peak-side input matching circuit 9.

The carrier-side input matching circuit 8 performs impedance matching, with respect to a fundamental frequency between the divider 6 side and the carrier amplifier 4 side. The peak-side input matching circuit 9 performs impedance matching with respect to the fundamental frequency between the divider 6 side and the peak amplifier 5 side.

The carrier amplifier 4 is an amplifier for constantly amplifying an input signal provided thereto. On the other hand, the peak amplifier 5 is an amplifier for amplifying an input signal when the power of the input signal becomes equal to or higher than a predetermined value. Each of the carrier amplifier 4 and the peak amplifier 5 is, for example, a high electron mobility transistor (HEMT) using gallium nitride (GaN).

The carrier amplifier 4 and the peak amplifier 5 are mounted on an integrated circuit, and are housed in a package 20.

An output from the carrier amplifier 4 is provided to the combiner 7 via the carrier-side output matching circuit 10.

An output from the peak amplifier 5 is provided to the combiner 7 via the peak-side output matching circuit 11.

The carrier-side output matching circuit 10 performs impedance matching with respect to the fundamental frequency between the carrier amplifier 4 side and the combiner 7 side. The peak-side output matching circuit 11 performs impedance matching with respect to the fundamental frequency between the peak amplifier 5 side and the combiner 7 side.

The combiner 7 combines the output from the carrier amplifier 4 and the output from the peak amplifier 5. The combiner 7 provides, as an output signal, the combined output to the output terminal 3.

The output terminal 3 outputs the output signal provided from the combiner 7.

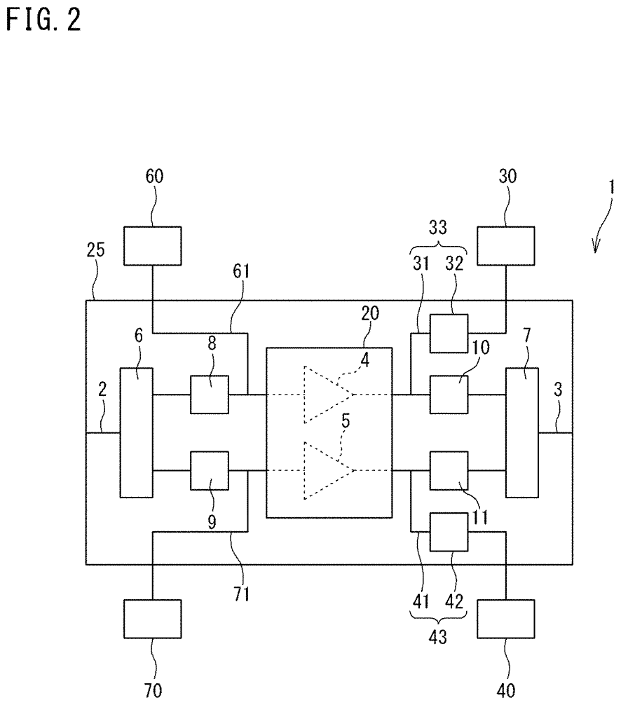

FIG. 2 is a plan view of the Doherty amplification circuit 1.

As shown in FIG. 2, the package 20 housing the amplifiers 4 and 5, the input and output terminals 2 and 3, the divider 6, the combiner 7, and the matching circuits 8, 9, 10, and 11 are mounted on a circuit board 25.

A first drain power supply 30, a second drain power supply 40, a first gate power supply 60, and a second gate power supply 70, which are disposed outside the circuit board 25, are connected to the Doherty amplification circuit 1.

The first drain power supply 30 is a power supply for supplying a drain voltage to be applied to the carrier amplifier 4, and is connected to a drain terminal of the carrier amplifier 4 via a first feeder line 31.

The second drain power supply 40 is a power supply for supplying a drain voltage to be applied to the peak amplifier 5, and is connected to a drain terminal of the peak amplifier 5 via a second feeder line 41.

The first gate power supply 60 is a power supply for supplying a gate voltage to be applied to the carrier amplifier 4, and is connected to a gate terminal of the carrier amplifier 4 via a third feeder line 61.

The second gate power supply 70 is a power supply for supplying a gate voltage to be applied to the peak amplifier 5, and is connected to a gate terminal of the peak amplifier 5 via a fourth feeder line 71.

A first setting unit 32 is connected to the first feeder line 31. The first setting unit 32 performs harmonic processing for the output from the carrier amplifier 4 to be provided to the carrier-side output matching circuit 10.

A second setting unit 42 is connected to the second feeder line 41. The second setting unit 42 performs harmonic processing for the output from the peak amplifier 5 to be provided to the peak-side output matching circuit 11.

The first setting unit 32 and the second setting unit 42 perform processing (harmonic processing) for adjusting, to appropriate values, impedances to harmonics in signals in the carrier-side output matching circuit 10 and the peak-side output matching circuit 11, respectively.

The first feeder line 31 and the first setting unit 32 connected to the first feeder line 31 form a first harmonic processing circuit 33.

The second feeder line 41 and the second setting unit 42 connected to the second feeder line 41 form a second harmonic processing circuit 43.

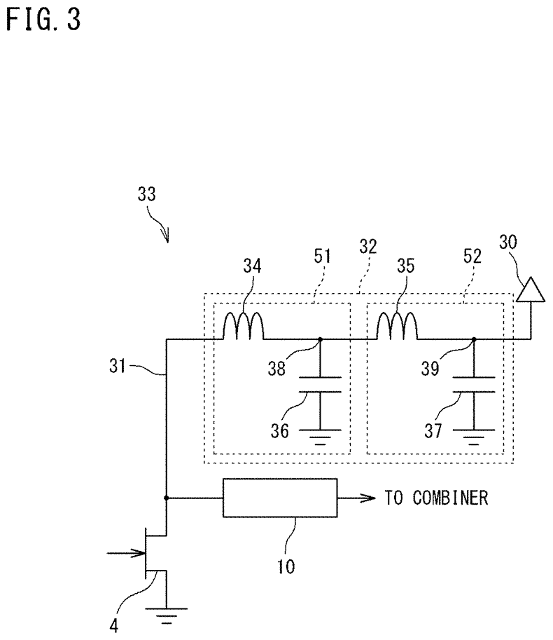

FIG. 3 is a block diagram showing the configuration of the first harmonic processing circuit 33. The second harmonic processing circuit 43 has the same configuration as the first harmonic processing circuit 33. Therefore, only the first harmonic processing circuit 33 will be described hereinafter.

As shown in FIG. 3, the first harmonic processing circuit 33 is configured to include a first inductive element 34, a second inductive element 35, a first capacitive element 36, and a second capacitive element 37.

These elements 34, 35, 36, and 37 are lumped elements, and the first harmonic processing circuit 33 is configured as a lumped circuit.

The first inductive element 34 and the second inductive element 35 are connected to the first feeder line 31.

One end of the first capacitive element 36 is connected to a connection point 38 between the first inductive element 34 and the second inductive element 35, while the other end thereof is grounded.

One end of the second capacitive element 37 is connected to a connection point 39 between the second inductive element 35 and the first drain power supply 30, while the other end thereof is grounded. Therefore, the first capacitive element 36 and the second capacitive element 37 are connected in parallel.

Thus, the first harmonic processing circuit 33 is configured to include a first LC circuit 51 composed of the first inductive element 34 and the first capacitive element 36, and a second LC circuit 52 composed of the second inductive element 35 and the second capacitive element 37. That is, the first harmonic processing circuit 33 is configured by connecting two stages of LC circuits.

According to the first harmonic processing circuit 33 of the present embodiment, since at least part of the first setting unit 32 (second setting unit 42) for setting an impedance to a harmonic is configured by a lumped circuit, the size of the first setting unit 32 (second setting unit 42) can be reduced as compared to the case where harmonic processing is performed using an open stub as in the aforementioned conventional art, for example, thereby achieving miniaturization of the entire circuit.

In the present embodiment, the first setting unit 32 (second setting unit 42) is provided to the first feeder line 31 (second feeder line 41) to use the first feeder line 31 (second feeder line 41) as a branch line, the branch line branching from the carrier-side output matching circuit 10 (peak-side output matching circuit 11) as a signal line.

In this case, since the existing first feeder line 31 (second feeder line 41) is used as a branch line, the first setting unit 32 (second setting unit 42) can be provided without adding a new line.

Thus, even when the Doherty amplification circuit 1 including the amplifiers 4 and 5 is provided with the harmonic processing circuit, the Doherty amplification circuit 1 is inhibited from being increased in size due to the harmonic processing circuit.

In the present embodiment, the first setting unit 32 (second setting unit 42) is set such that the first feeder line 31 (second feeder line 41) is open with respect to the fundamental frequency of the signal in the carrier-side output matching circuit 10 (peak-side output matching circuit 11).

In this case, the first setting unit 32 (second setting unit 42) is inhibited from adversely affecting the fundamental frequency.

In the present embodiment, the first setting unit 32 includes a plurality of (two) capacitive elements 36 and 37 connected in parallel. Of these capacitive elements 36 and 37, the second capacitive element 37, which is connected in a position adjacent to the first drain power supply 30, is set to a capacitance that causes a short circuit with respect to the fundamental frequency of the signal in the carrier-side output matching circuit 10.

Thus, a high-frequency signal is prevented from leaking to a voltage source side of the feeder line.

In the present embodiment, the inductance of the second inductive element 35 is set to a value greater than the inductance of the first inductive element 34, and the capacitance of the second capacitive element 37 is set to a value greater than the capacitance of the first capacitive element 36.

Through settings that satisfy the above relationships, the values of the respective elements can be appropriately set while satisfying the capacitance of the second capacitive element 37 and other conditions.

There are cases where the capacitance of the first capacitive element 36 is set to an extremely small value. Therefore, the first capacitive element 36 need not be connected between the first inductive element 34 and the second inductive element 35.

In the present embodiment, since both the carrier amplifier 4 and the peak amplifier 5 are housed in the single package 20, the carrier-side output matching circuit 10 and the peak-side output matching circuit 11 are arranged adjacent to each other (FIG. 2), whereby the space around the matching circuits 10 and 11 is limited. Even in this case, since the first harmonic processing circuit 33 of the present embodiment can achieve miniaturization of the entirety thereof, appropriate arrangement can be achieved even when the space around the matching circuits 10 and 11 is limited.

### EXAMPLES

Hereinafter, an example of a harmonic processing circuit will be described.

As an example, an amplification circuit, which includes an amplifier that amplifies an RF signal having a frequency of 2.6 GHz, and a harmonic processing circuit provided to a feeder line of this amplifier, is assumed. A load impedance of this amplification circuit was obtained.

The harmonic processing circuit according to the example has the same configuration as the first harmonic processing circuit 33 shown in FIG. 3. That is, the harmonic processing circuit includes a first inductive element 34, a second inductive element 35, a first capacitive element 36, and a second capacitive element 37, so that two stages of LC circuits are connected.

This harmonic processing circuit was set to perform harmonic processing for a double wave with a frequency of 2.6 GHz. More specifically, the values of the respective elements were set such that the phase of the double wave (frequency: 5.2 GHz) was about 85 degrees. Note that the second capacitive element is set to a capacitance that causes a short circuit with respect to the fundamental frequency.

Examples of set values of the respective elements in this example are as follows.
First inductive element: 2.2 nH
Second inductive element: 3.3 nH
First capacitive element: 0.5 pF
Second capacitive element: 10 pF

Load impedances of the amplifier in this case were obtained through a simulation using a computer.

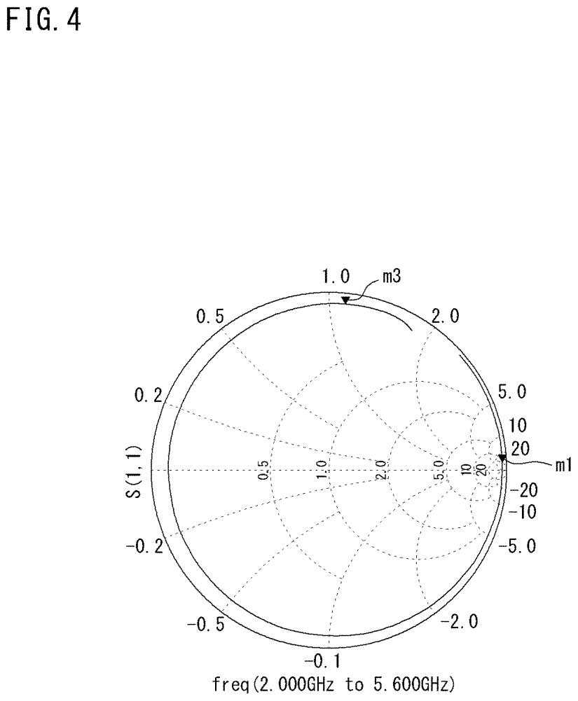

FIG. 4 is a Smith chart showing load impedances in response to frequency change in the signal in the amplification circuit according to the example.

In FIG. 4, a marker ml indicates a load impedance at a frequency of 2.6 GHz. A marker m3 indicates a load impedance at a frequency of 5.2 GHz.

The load impedance of the marker m1 has a magnitude of 0.978 and a phase of 2.433, and is substantially open.

The load impedance of the marker m3 has a magnitude of 0.943 and a phase of 84.285, which allows execution of harmonic processing almost as intended.

### [Others]

Note that the embodiment disclosed herein is merely illustrative in all aspects and should not be recognized as being restrictive.

For example, although the Doherty amplification circuit 1 has been described in the above embodiment, the embodiment is also applicable to an amplification circuit using a package housing a single amplifier.

In the above embodiment, the first setting unit 32 is configured by connecting two stages of LC circuits. However, more stages, such as three stages or four stages, of LC circuits may be connected. For example, two stages of LC circuits being connected enable harmonic processing up to a second-order harmonics, and three stages of LC circuits being connected enable harmonic processing up to a third-order harmonic. Thus, the number of LC circuits to be connected is set according to the order of a harmonic to be processed.

In the above embodiment, the first setting unit 32 includes the elements 34, 35, 36, and 37 each being configured by a lumped element. However, for example, the first inductive element 34 and the second inductive element may be used in combination with transmission lines or may be replaced by transmission lines. In this case, each of the first inductive element 34 and the second inductive element 35 is configured by a distributed element, while each of the first capacitive element 36 and the second capacitive element 37 is configured by a lumped element. Therefore, in this case, at least part of the first setting unit 32 is configured by a lumped circuit.

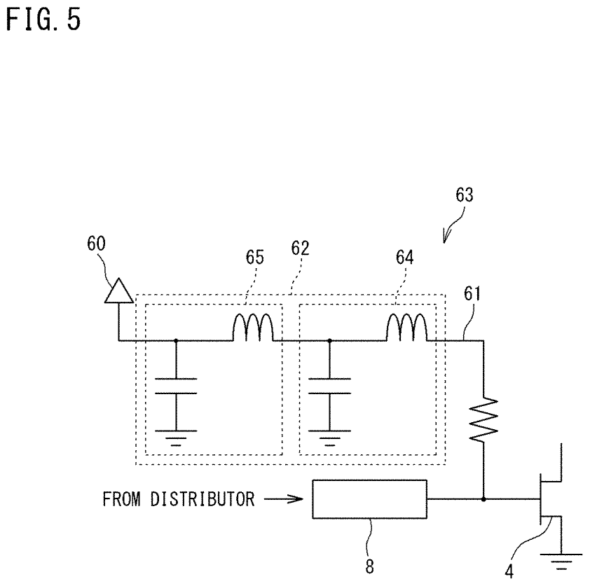

In the above embodiment, the first harmonic processing circuit 33 and the second harmonic processing circuit 43 are provided to the first feeder line 31 connected to the drain terminal of the carrier amplifier 4 and to the second feeder line 41 connected to the drain terminal of the peak amplifier 5, respectively. However, as shown in FIG. 5, a setting unit 62 may be provided to the third feeder line 61 for supplying a gate voltage from the first gate power supply 60, thereby providing a harmonic processing circuit 63. The setting unit 62 has the same configuration as the first setting unit 32 of the above embodiment, and is configured by connecting two stages of LC circuits 64 and 65.

The same applies to the second gate power supply 70, and a harmonic processing circuit may be provided to the fourth feeder line 71.

In this case, when the setting unit 62, which sets an impedance on the signal source side of the carrier amplifier 4 and the peak amplifier 5, is configured by a lumped circuit, the size of the setting unit 62 can be reduced, whereby miniaturization of the entire harmonic processing circuit 63 can be achieved. Moreover, miniaturization of the entire Doherty amplification circuit 1 can be achieved.

The scope of the present invention is defined by the scope of the claims rather than by the meaning described above, and is intended to include meaning equivalent to the scope of the claims and all modifications within the scope.

### REFERENCE SIGNS LIST

1 Doherty amplification circuit

2 input terminal

3 output terminal

4 carrier amplifier

5 peak amplifier

6 divider

7 combiner

8 carrier-side input matching circuit

9 peak-side input matching circuit

10 carrier-side output matching circuit

11 peak-side output matching circuit

20 package

25 circuit board

30 first drain power supply

31 first feeder line

32 first setting unit

33 first harmonic processing circuit

34 first inductive element

35 second inductive element

36 first capacitive element

37 second capacitive element

38 connection point

39 connection point

40 second drain power supply

41 second feeder line

42 second setting unit

43 second harmonic processing circuit

51 first LC circuit

52 second LC circuit

60 first gate power supply

61 third feeder line

62 setting unit

63 harmonic processing circuit

64, 65 LC circuit

70 second gate power supply

71 fourth feeder line

1. A harmonic processing circuit comprising:
a branch line branching from a signal line configured to transmit a signal to be inputted to or outputted from an amplifier; and
a setting unit connected to the branch line and configured to set an impedance in the signal line to a harmonic of the signal, wherein
at least part of the setting unit is configured by a lumped circuit.

2. The harmonic processing circuit according to claim 1, wherein the branch line is a feeder line for the amplifier.

3. The harmonic processing circuit according to claim 1, wherein the setting unit is set such that the branch line is open with respect to a fundamental frequency of the signal.

4. The harmonic processing circuit according to claim 1, wherein the amplifier is housed in a single package together with another amplifier.

5. The harmonic processing circuit according to claim 1, wherein
the setting unit includes a plurality of capacitive elements connected in parallel, and
a capacitance of a capacitive element connected in a position adjacent to a voltage source for applying a voltage to the feeder line among the plurality of capacitive elements is a capacitance that causes a short circuit with respect to the fundamental frequency of the signal.

6. The harmonic processing circuit according to claim 1, wherein the setting unit includes:
a first inductive element connected to the branch line;
a second inductive element connected between the first inductive element and the voltage source for applying a voltage to the feeder line;
a first capacitive element having an end connected to a connection point between the first inductive element and the second inductive element; and
a second capacitive element having an end connected to a connection point between the second inductive element and the voltage source, wherein
an inductance of the second inductive element is a value greater than an inductance of the first inductive element, and
a capacitance of the second capacitive element is a value greater than a capacitance of the first capacitive element.

7. An amplification circuit comprising:
an amplifier;
a signal line configured to transmit a signal to be inputted to or outputted from the amplifier; and
the harmonic processing circuit according to claim 1.
